(19) United States
(12) Patent Application Publication
(10) Pub. No.: US 2010/0258850 A1
(43) Pub. Date: Oct. 14, 2010

(54) SEMICONDUCTOR INTEGRATED DEVICE

(75) Inventor: Takashi AOI, Kanagawa-ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/712,528

(22) Filed: Feb. 25, 2010

(30) Foreign Application Priority Data
Apr. 14, 2009 (JP) 2009-098251

(51) Int. Cl. H01L 29/788

(52) U.S. Cl. 257/316; 257/E29.3

(57) ABSTRACT

A semiconductor integrated device including a capacitor having a structure suitable for a larger capacitance is disclosed. A first electrode layer is electrically isolated by a first device isolation layer. An interelectrode insulating film is formed on the first electrode layer and the first device isolation layer and having an opening extending to the first electrode layer. A first electrode portion is formed on the interelectrode insulating film and electrically connected to the first electrode layer through the opening. A second electrode portion is formed on the interelectrode insulating film and electrically isolated from the first electrode layer. A third electrode portion is formed so as to penetrate through the interelectrode insulating film from a lower surface of the second electrode portion formed above the first device isolation layer, then to protrude inside the first device isolation layer, and to face side surfaces of the first electrode layer.

### CROSS REFERENCE TO RELATED APPLICATION

This application is based upon and claims the benefit of priority from the prior Japanese Patent Application No. 2009-098251, filed on Apr. 14, 2009, the entire contents of which are incorporated herein by reference.

### FIELD OF THE INVENTION

The invention relates to a semiconductor integrated device.

### DESCRIPTION OF THE BACKGROUND

Semiconductor integrated devices (semiconductor chips) including non-volatile memory cells such as an electrically programmable ROM (EPROM), an electrically erasable and programmable ROM (EEPROM), and a flash memory have a stacked gate structure in which a memory cell formation region includes a floating gate electrode layer and a control gate electrode layer.

In addition, together with the memory cells, a peripheral circuit such as a control circuit necessary to drive the memory cells is formed on the same substrate of the semiconductor integrated device.

A region of the peripheral circuit includes thin-film elements such as a transistor, a resistor and a capacitor necessary for each circuit. These elements are desirably formed by one process together with a memory cell portion in order to reduce the manufacturing steps.

For example, when attention is paid to a structure of a capacitor for use in a peripheral circuit, a semiconductor integrated device including a flash memory has the following capacitor structure. Specifically, an intergate insulating film (second gate insulating film) formed between a floating gate electrode layer and a control gate electrode layer is used as an electric charge storage layer of the capacitor. A semiconductor device of this type is disclosed in Japanese Patent Application Publication No. 2002-141469.

The semiconductor device has a structure in which a first electrode layer, an interelectrode insulating film, and a second electrode layer are stacked in this order in a main circuit region on a semiconductor substrate. In a peripheral circuit region on the semiconductor substrate, the semiconductor device includes a first electrode layer, an interelectrode insulating film that is formed on the first electrode layer and that has an opening extending to the first electrode layer, a first region of a second electrode layer that is formed over the opening and on the interelectrode insulating film located around the opening and that is electrically connected to the first electrode layer through the opening, and a second region of the second electrode layer that is formed on the interelectrode insulating film and that is electrically isolated from the first region of the second electrode layer.

However, in the semiconductor device, the first electrode layer and the second electrode layer are stacked to extend in a direction parallel to the semiconductor substrate. For this reason, if there is not enough capacitance, areas of the first electrode layer and the second electrode layer need to be increased in order to increase the capacitance.

Since this leads to an increase in chip size, there is a problem that shrinking of the chip size by miniaturization of elements is inhibited.

### SUMMARY OF THE INVENTION

One aspect of the invention is to provide a semiconductor integrated device including a main circuit and a peripheral circuit, the main circuit being formed in a first region on a main surface of a semiconductor substrate and having a first portion of a first electrode layer, a first portion of an interelectrode insulating film and a first portion of a second electrode layer respectively stacked in the order, the peripheral circuit being formed in a second region on the main surface of the semiconductor substrate and including, a second portion of the first electrode layer electrically isolated by a first device isolation layer, a second portion of the interelectrode insulating film formed on the second portion of the first electrode layer and the first device isolation layer and having an opening extending to the second portion of the first electrode layer, a first electrode portion of a second portion of the second electrode layer formed on the second portion of the interelectrode insulating film and electrically connected to the second portion of the first electrode layer through the opening, a second electrode portion of the second portion of the second electrode layer formed on the second portion of the interelectrode insulating film and electrically isolated from the second portion of the first electrode layer, and a third electrode portion of the second portion of the second electrode layer formed so as to penetrate through the second portion of the interelectrode insulating film from a lower surface of the second electrode portion of the second portion of the second electrode layer formed above the first device isolation layer, then to protrude inside the first device isolation layer, and to face side surfaces of the second portion of the first electrode layer.

Another aspect of the invention is to provide a semiconductor integrated device including,

a first electrode layer electrically isolated by a first device isolation layer, an interelectrode insulating film formed on the first electrode layer and the first device isolation layer and having an opening extending to the first electrode layer, a first electrode portion of a second electrode layer formed on the interelectrode insulating film and electrically connected to the first electrode layer through the opening, a second electrode portion of the second electrode layer formed on the interelectrode insulating film and electrically isolated from the first electrode layer, and a third electrode portion of the second electrode layer formed so as to penetrate through the interelectrode insulating film from a lower surface of the second electrode portion of the second portion of the second electrode layer formed above the first device isolation layer, then to protrude inside the first device isolation layer, and to face side surfaces of the first electrode layer.

### BRIEF DESCRIPTION OF THE DRAWINGS

FIGS. 1A, 1B and 1C are views each showing a semiconductor integrated device according to an embodiment of the invention. FIG. 1A is a plan view of the semiconductor integrated device. FIG. 1B is a cross-sectional view taken along a line A-A of FIG. 1A, and viewed from a direction indicated by arrows A. FIG. 1C is a cross-sectional view taken along a line B-B of FIG. 1A, and viewed from a direction indicated by arrows B.

FIG. 2 is a cross-sectional view showing a main portion of the semiconductor integrated device according to the embodiment of the invention.

FIG. 3 is a cross-sectional view showing a main portion of a semiconductor integrated device of a comparative example according to the embodiment of the invention.

FIGS. 4A, 4B and 4C are cross-sectional views each showing a main portion in the order of manufacturing steps of the semiconductor integrated device according to the embodiment of the invention.

FIGS. 5A, 5B and 5C are cross-sectional views each showing a main portion in the order of manufacturing steps of the semiconductor integrated device according to the embodiment of the invention.

FIG. 6 is a plan view showing first regions and second regions of the semiconductor integrated device according to the embodiment of the invention.

FIG. 7 is a circuit diagram showing a main circuit of the semiconductor integrated device according to the embodiment of the invention.

FIGS. 8A, 8B and 8C are views each showing the main circuit of the semiconductor integrated device according to the embodiment of the invention. FIG. 8A is a plan view of the main circuit. FIG. 8B is a cross-sectional view taken along a line A-A of FIG. 8A, and viewed from a direction indicated by arrows A. FIG. 8C is a cross-sectional view taken along a line B-B of FIG. 8A, and viewed from a direction indicated by arrows B.

FIG. 9 is a circuit diagram showing a charge pump circuit of the semiconductor integrated device according to the embodiment of the invention.

### DETAILED DESCRIPTION OF THE INVENTION

Embodiments of the invention will be described hereinafter with reference to the drawings.

### Embodiment

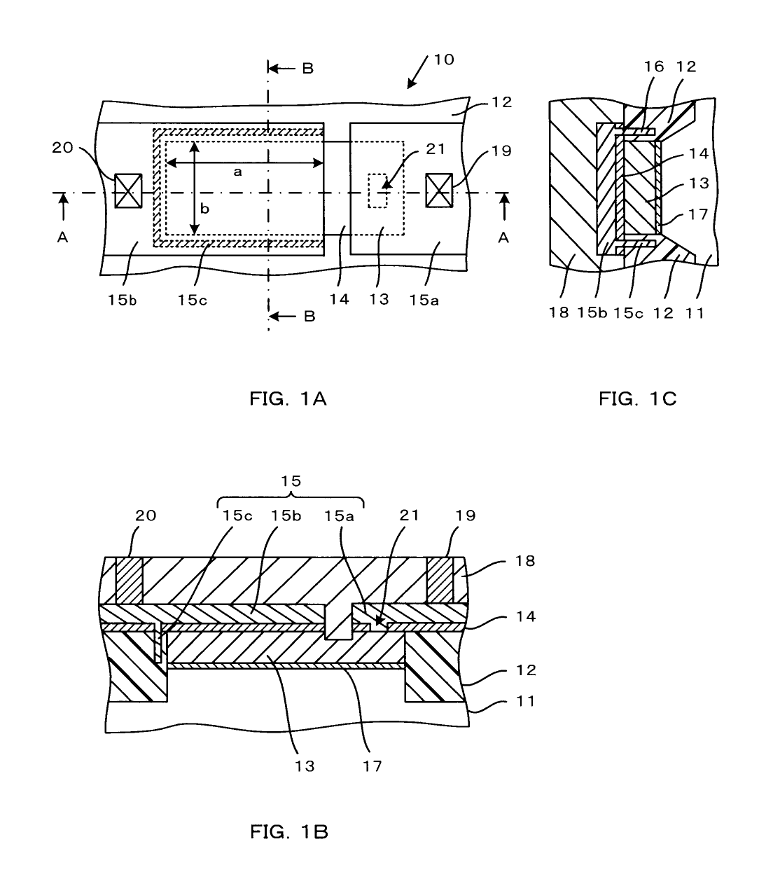

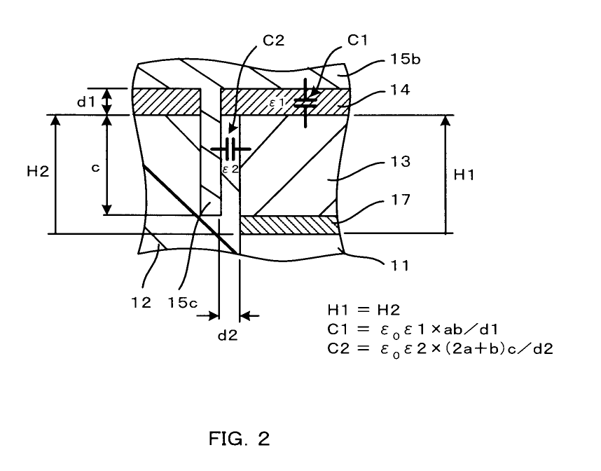

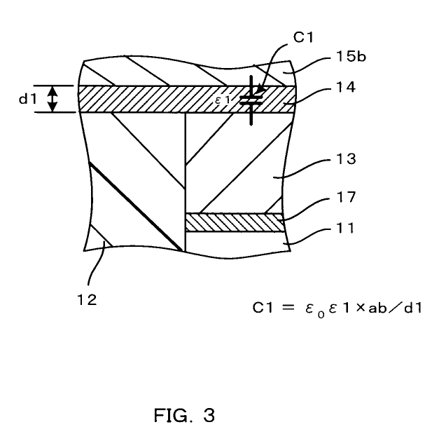

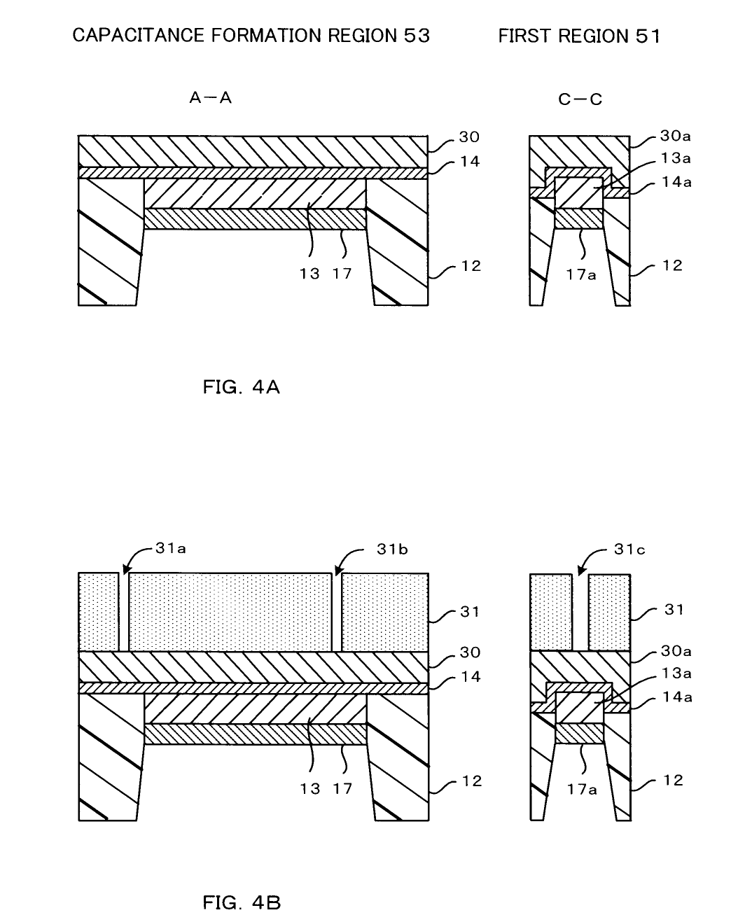

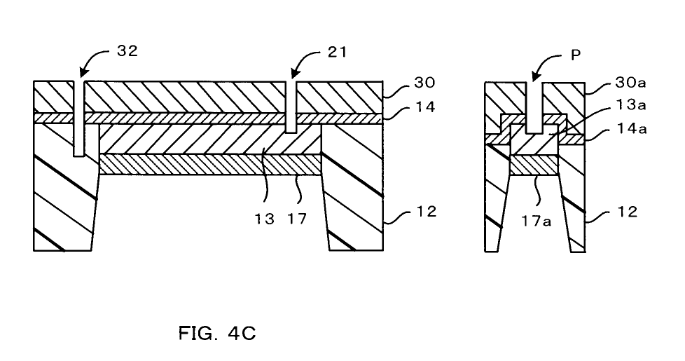

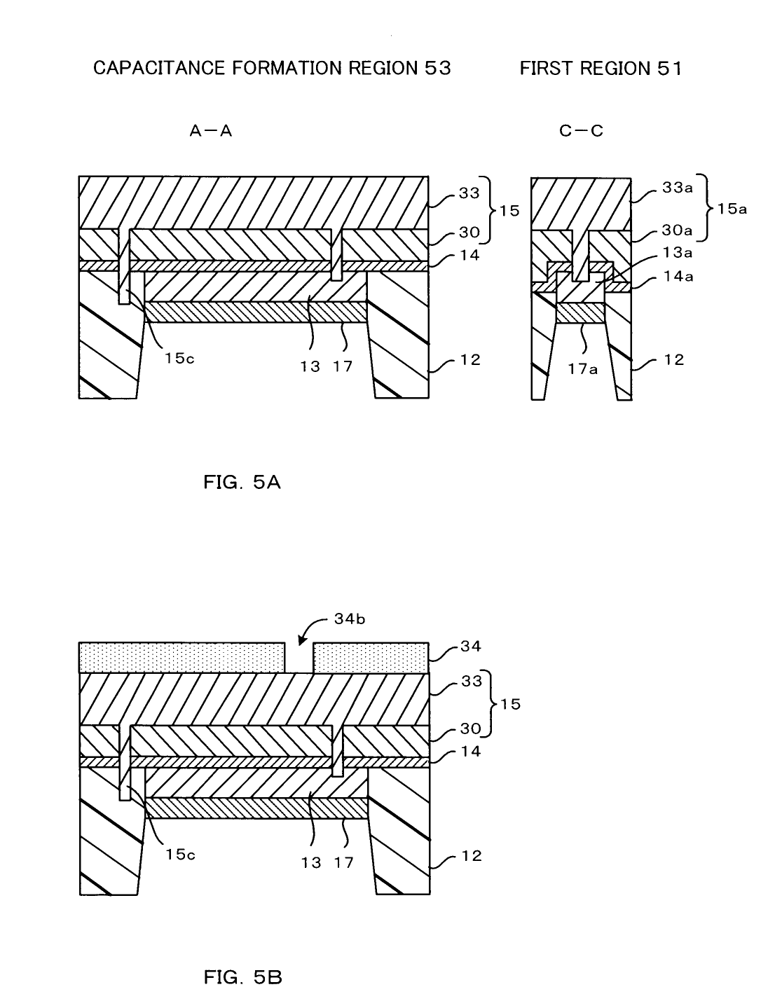

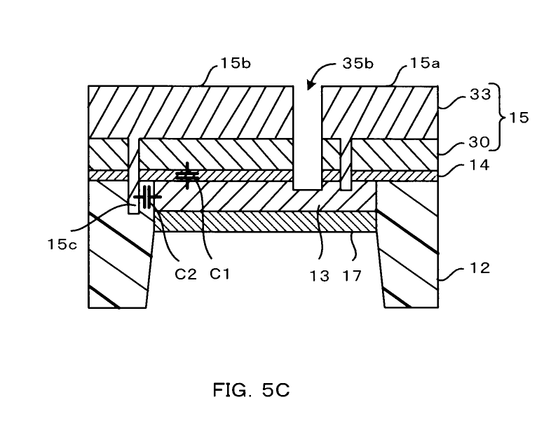

A semiconductor integrated device according to an embodiment of the invention will be described with reference to FIGS. 1A to 5C. FIGS. 1A, 1B and 1C are views each showing the semiconductor integrated device. FIG. 1A is a plan view of the semiconductor integrated device. FIG. 1B is a cross-sectional view taken along a line A-A of FIG. 1A, and viewed from a direction indicated by arrows A. FIG. 1C is a cross-sectional view taken along a line B-B of FIG. 1A, and viewed from a direction indicated by arrows B. FIG. 2 is a cross-sectional view showing a main portion of the semiconductor integrated device. FIG. 3 is a cross-sectional view showing the main portion of a semiconductor integrated device of a comparative example. FIGS. 4A to 5C are cross-sectional views each showing a main portion in the order of manufacturing steps of the semiconductor integrated device.

The embodiment is an example of a case of an NAND type EEPROM in which a semiconductor integrated device includes an NAND cell. To form the NAND cell, adjacent source/drain diffusion layers of multiple memory transistors are connected to one another in series in a shared manner.

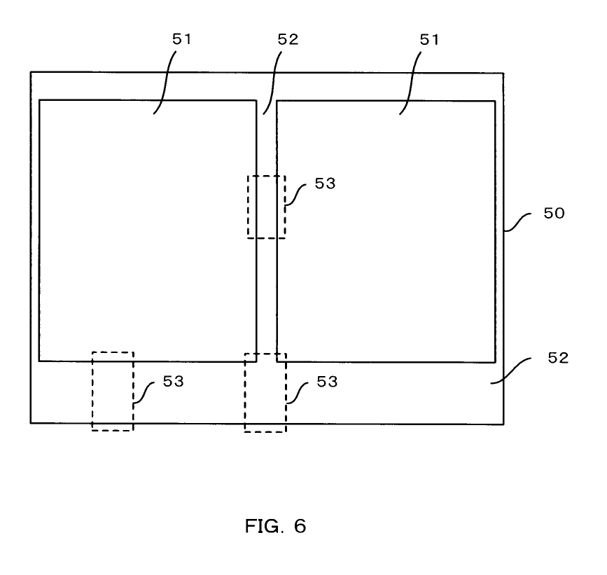

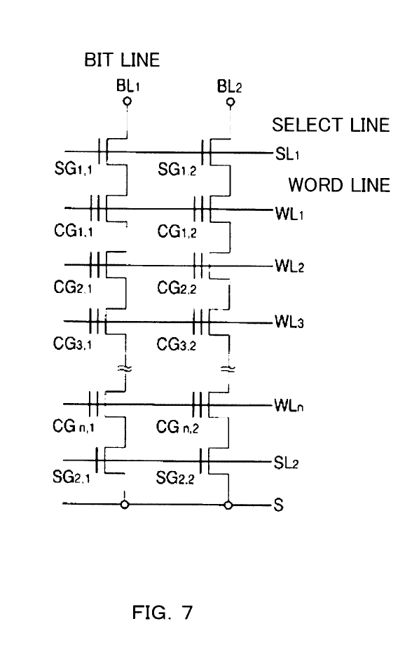

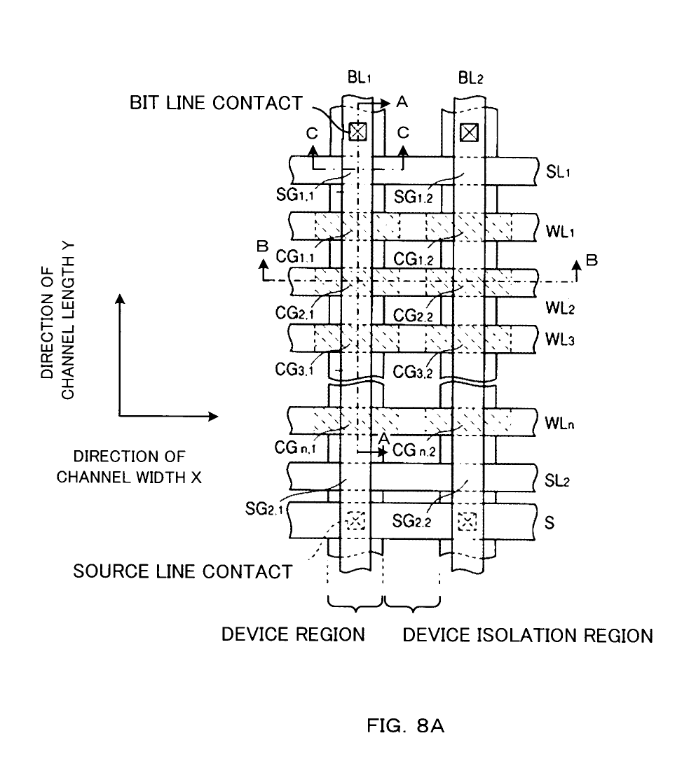

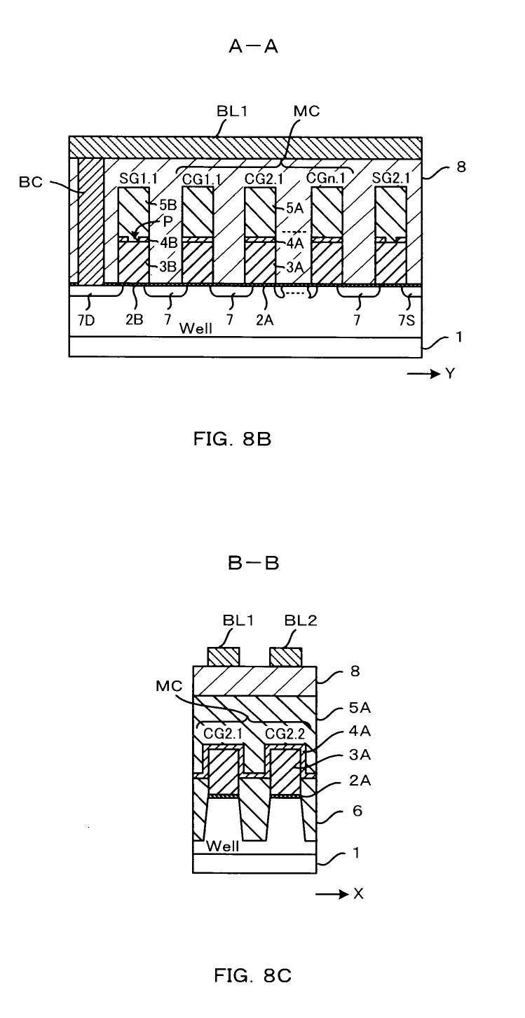

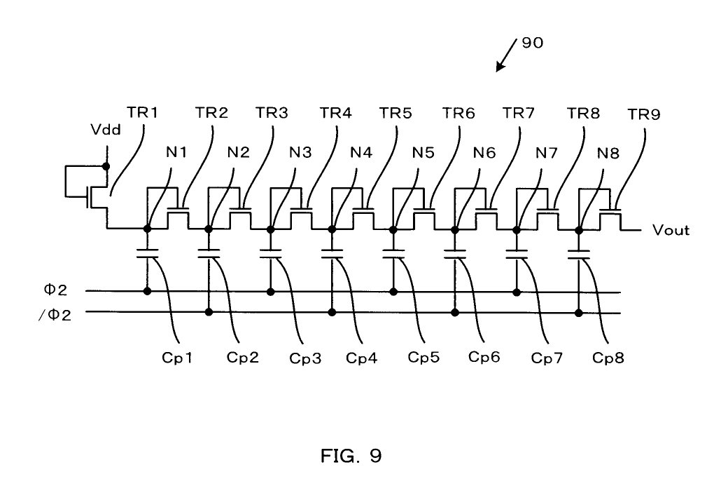

Firstly, a general description of the semiconductor integrated device of the embodiment will be given with reference to FIGS. 6 to 9. FIG. 6 is a plan view showing first regions and second regions of the semiconductor integrated device. FIG. 7 is a circuit diagram showing a main circuit (memory cell array) of the semiconductor integrated device. FIGS. 8A, 8B and 8C are views each showing the main circuit of the semiconductor integrated device. FIG. 8A is a plan view of the main circuit. FIG. 8B is a cross-sectional view taken along a line A-A of FIG. 8A. FIG. 8C is a cross-sectional view taken along a line B-B of FIG. 8A. FIG. 9 is a circuit diagram showing a charge pump circuit of the semiconductor integrated device.

As shown in FIG. 6, the semiconductor integrated device of the embodiment includes first regions 51 and second regions 52 on a main surface of a semiconductor chip (semiconductor substrate) 50. In each of the first regions 51, a memory cell array of an NAND type EEPROM including memory transistors is formed. Each of the memory transistors has a first gate electrode film (tunnel insulating film), a floating gate electrode layer, a second gate insulating film (IPD film) and a control gate electrode layer. In each of the second regions 52, a peripheral circuit including a control circuit or the like necessary to drive memory cells is formed.

The control circuit includes circuit elements such as a transistor, a resistor and a capacitor. These elements are formed simultaneously with a memory cell portion in order to reduce the b manufacturing steps. For example, a capacitor of a large capacitance for use in a charge pump circuit is formed in each of capacitor formation regions 53. The charge pump circuit is used to supply a high voltage to a memory cell.

In the memory cell array of the NAND type EEPROM provided in each first region 51, a single NAND type memory cell is configured in the following manner. As shown in FIG. 7, a plurality of memory transistors CG1.1, CG2.1, CG3.1 . . . CGn.1 are connected in series. Here, the plurality of memory transistors CG1.1, CG2.1, CG3.1 . . . CGn.1 are each formed of an N-channel MOS transistor in which a floating gate electrode and a control gate electrode are stacked on one another. A drain of the transistor on one end is connected to a bit line BL1 by a bit line contact through a select NMOS transistor SG1.1, while a source of the transistor on the other end is connected to a source line S by a source line contact through a select NMOS transistor SG2.1.

Similarly, the second line of SG1.2, CG1.2, CG2.2, CG3.2 . . . CGn.2, SG2.2 also constitute a single NAND type memory cell, and multiple NAND type memory cell groups are arranged in an array so as to constitute a memory cell array.

As shown in FIG. 8A, each of the transistors in the memory cell array is formed in the same well region of a semiconductor substrate, and the control gate electrodes of the memory transistors CG1.1, CG2.1, CG3.1 . . . CGn.1 (CG1.2, CG2.2, CG3.2 . . . CGn.2) are provided continuously in a row direction approximately orthogonal to the bit line BL so as to constitute word lines WL1, WL2, . . . WLn, respectively.

Similarly, the control gate electrodes of the select transistors SG1.1, SG1.2 (SG2.1, SG2.2) are also provided continuously so as to constitute select lines SL1, SL2, respectively.

As shown by hatching of broken lines, the floating gate electrodes of each memory cell are isolated in separation under the control gate electrodes of the respective transistors.

As shown in FIGS. 8B, 8C, a gate structure of each of memory cells MC is a structure in which a control gate electrode 5A is stacked on a floating gate electrode 3A through an intergate insulating film 4A.

A well region Well is provided in a semiconductor substrate 1 (element region), to which the memory cells MC are provided. Gate insulating film 2A is formed on a surface of the semiconductor substrate 1. In each memory cell MC, the gate insulating film 2A as a tunnel insulating film. Hereinafter, the gate insulating film 2A in the memory cell MC is referred to as a tunnel insulating film 2A.

The floating gate electrode 3A is provided on the tunnel insulating film 2A on the surface of the semiconductor substrate 1. The floating gate electrode 3A as an electric charge storage layer to store data to the corresponding memory cell, and is formed of a polysilicon film, for example.

The intergate insulating film 4A is provided on the floating gate electrode 3A, while the control gate electrode 5A is provided on the intergate insulating film 4A. In order to reduce electrical resistance, the control gate electrode 5A has a double layer structure (polycide structure) in which a silicide film is stacked on a polysilicon film, for example.

However, the structure of the control gate electrode 5A is not limited to the double layer structure. Instead, the control gate electrode 5A may have a single layer structure of a polysilicon film or a single layer structure of a silicide film. For example, a tungsten silicide film (WSi₂), a molybdenum silicide film (MoSi₂), a cobalt silicide film (CoSi₂), a titanium silicide film (TiSi₂), a nickel silicide film (NiSi₂) or the like is used as a silicide film.

The control gate electrode 5A functions as the word line WL2, for example, and the control gate electrode 5A is shared between memory cells adjacent in an x-direction, as described above. Accordingly, the control gate electrode 5A is provided not only on the floating gate electrode 3A but also on a device isolation insulating film 6 in a device isolation insulating region STI, through the intergate insulating film 4A.

The upper end of the device isolation insulating film 6 is located at a position lower than the upper end of the floating gate electrode 3A (on the semiconductor substrate side). Accordingly, side surfaces of the floating gate electrode 3A in the x-direction (channel width direction) are covered by the control gate electrode 5A through the intergate insulating film 4A.

For this reason, a facing surface between the floating gate electrode 3A and the control gate electrode 5A is secured not only on an upper surface of the floating gate electrode 3A but also on side surfaces of the floating gate electrode 3A. Thus, the coupling ratio of the memory cell MC is improved.

Diffusion layers 7 are provided in the semiconductor substrate 1. The diffusion layers 7 function as source/drain regions of the memory cells MC. Each of the diffusion layers 7 is shared by the memory cells MC adjacent to the diffusion layer 7 in a Y-direction (channel length direction). Thus, multiple memory cells MC are connected together in series.

The select transistors SG1.1, SG2.1 are provided at one and the other ends, respectively, of the multiple memory cells MC (NAND strings) connected together in series.

The select transistors SG1.1, SG2.1 are formed in the same step in which the memory cells MC. Thus, a gate structure of each of the select transistors SG1.1, SG2.1 is such that a gate electrode 5B is stacked on a gate electrode 3B through an intergate insulating film 4B, as is the case with the memory cells MC.

However, in the select transistors SG1.1, SG2.1, the intergate insulating film 4B includes an opening P through which the gate electrode 3B on a gate insulating film 2B is connected to the gate electrode 5B on the intergate insulating film 4B.

The diffusion layers 7, 7D, 7S function as source/drain regions of the select transistors SG1.1, SG2.1, and are shared by the memory cells MC adjacent to the select transistors SG1.1, SG2.1 in the Y-direction. Thus, the plurality of memory cells MC and the select transistors SG1.1, SG2.1 are connected together in series in the Y-direction so as to constitute a single NAND cell unit.

In the NAND cell unit, the diffusion layer 7D of select transistor SG1.1, which is located on the drain side of the NAND string, is connected to the bit line BL1 through a bit line contact portion BC buried in an interlayer insulating film 8. In addition, the diffusion layer 7S of the select transistor SG2.1, which is located on the source side of the NAND string, is connected to a source line (not illustrated) through a source line contact (not illustrated) buried in the interlayer insulating film 8.

As shown in FIG. 9, a charge pump circuit 90 includes nine N-channel MOS transistors TR1 to TR9 and eight capacitors Cp1 to Cp8. Note that the numbers of MOS transistors and capacitors are not limited to the embodiment and that three or more capacitors may be sufficient. Additionally, hereinafter, when the MOS transistors TR1 to TR9 and the capacitors Cp1 to Cp8 are not distinguished from each other, the MOS transistors TR1 to TR9 and the capacitors Cp1 to Cp8 are simply described as MOS transistor TRs and capacitor Cs, in some cases.

In the MOS transistor TR1, one of a source and a drain is connected to a gate, and further connected to a power supply potential VDD. In the MOS transistor TR2, one of a source and a drain is connected to a gate (such a connection node is hereinafter referred to as a node N1), and further connected to the other of the source and the drain of the MOS transistor TR1.

In the MOS transistor TR3, one of a source and a drain is connected to a gate (such a connection node is hereinafter referred to as a node N2), and further connected to the other of the source and the drain of the MOS transistor TR2. In the MOS transistor TR4, one of a source and a drain is connected to a gate (such a connection node is hereinafter referred to as a node N3), and further connected to the other of the source and the drain of the MOS transistor TR3.

In the MOS transistor TR5, one of a source and a drain is connected to a gate (such a connection node is hereinafter referred to as a node N4), and further connected to the other of the source and the drain of the MOS transistor TR4. In the MOS transistor TR6, one of a source and a drain is connected to a gate (such a connection node is hereinafter referred to as a node N5), and further connected to the other of the source and the drain of the MOS transistor TR5.

In the MOS transistor TR7, one of a source and a drain is connected to a gate (such a connection node is hereinafter referred to as a node N6), and further connected to the other of the source and the drain of the MOS transistor TR6. In the MOS transistor TR8, one of a source and a drain is connected to a gate (such a connection node is hereinafter referred to as a node N7), and further connected to the other of the source and the drain of the MOS transistor TR7.

In the MOS transistor TR9, one of a source and a drain is connected to a gate (such a connection node is hereinafter referred to as a node N8), and further connected to the other of the source and the drain of the MOS transistor TR8. In addition, the other node of the source and the drain of the MOS transistor TR9 (such a connection node is hereinafter referred to as a node N9) is an output node of an output voltage Vout.

In other words, in the MOS transistor TR, one of a source and a drain functions as an anode, while the other of the source and the drain operates as a rectifier functioning as a cathode.

One electrodes of the capacitors Cp1, Cp3, Cp5, Cp7 are connected to the nodes N1, N3, N5, N7, respectively, while the other electrodes receive a clock ø2.

One electrodes of the capacitors Cp2, Cp4, Cp6, Cp8 are connected to the nodes N2, N4, N6, N8, respectively, while the other electrodes receive a clock/ø2. The clock/ø2 is an inversion signal of the clock ø2.

In other words, the charge pump circuit 90 includes multiple rectifiers connected together in series, and the clock ø2 is inputted to input nodes of rectifiers of even stages (MOS transistor TR2, TR4, TR6, . . . ) through capacitors Cpj (j=1, 3, 5, . . . ), respectively.

On the other hand, the clock/ø2 is inputted to input nodes of rectifiers of odd stages from and after the third stage (MOS transistor TR3, TR5, . . . ) through capacitors Cp (j+1), respectively.

As shown in FIGS. 1A to 1C, a semiconductor integrated device 10 of the embodiment has a peripheral circuit formed in the capacitor formation region 53 in each of the second regions 52. The peripheral circuit includes a first electrode layer 13, an interelectrode insulating film 14 and a second electrode layer 15 stacked on one another.

In the peripheral circuit, the first electrode layer 13 is electrically isolated from the surroundings by a device isolation layer 12 (first device isolation layer). The second electrode layer 15 is formed of a first electrode portion 15a, a second electrode portion 15b and a third electrode portion 15c.

The interelectrode insulating film 14, which includes an opening 21 extending to the first electrode layer 13, is formed on the first electrode layer 13 and the device isolation layer 12 (first device isolation layer).

The first electrode portion 15a of the second electrode layer 15, which is electrically connected to the first electrode layer 13 through the opening 21, is formed on the interelectrode insulating film 14.

The second electrode portion 15b of the second electrode layer 15, which is electrically isolated from the first electrode portion 15a, is formed on the interelectrode insulating film 14.

The third electrode portion 15c of the second electrode layer 15 is formed so as to penetrate through the interelectrode insulating film 14 from a lower surface of the second electrode portion 15b formed above the device isolation layer 12, then to protrude inside the device isolation layer 12, and to face side surfaces of the first electrode layer 13.

The opening 21 is formed on one end side of the first electrode layer 13, while the third electrode portion 15c is formed on the other end side of the first electrode layer 13.

As will be described later, the floating gate electrode layer, the second gate insulating film and the control gate electrode layer described in FIGS. 8B, 8C, as well as the first electrode layer 13, the interelectrode insulating film 14 and the second electrode layer 15 shown in FIGS. 1A to 1C, are layers and films of the same types formed in the same steps, respectively. These layers and film are collectively referred to as a first electrode layer, an interelectrode insulating film and a second electrode layer, respectively.

In other words, a first portion of the first electrode layer is the floating gate electrode layer shown in FIGS. 8B, 8C, a first portion of the interelectrode insulating film is the second gate insulating film shown in FIGS. 8B, 8C, and a first portion of the second electrode layer is the control gate electrode layer shown in FIGS. 8B, 8C. A second portion of the first electrode layer is the first electrode layer 13 shown in FIGS. 1A to 1C, a second portion of the interelectrode insulating film is the interelectrode insulating film 14 shown in FIGS. 1A to 1C, and a second portion of the second electrode layer is the second electrode layer 15 shown in FIGS. 1A to 1C.

The device isolation layer 12 is a shallow trench isolation (STI) obtained by burying an insulating material in a trench formed in a semiconductor substrate 11 so as to surround the first electrode layer 13.

The first electrode layer 13 is formed on a main surface of the semiconductor substrate 11 through an insulating film 17. The insulating film 17 secures electrical isolation of the first electrode layer 13 from a lower portion of the semiconductor substrate 11.

The second electrode portion 15b of the second electrode layer 15 overlaps with the first electrode layer 13 through the interelectrode insulating film 14. Here, unlike the first electrode portion 15a of the second electrode layer 15, the second electrode portion 15b of the second electrode layer 15 is electrically isolated from the first electrode layer 13. The third electrode portion 15c is formed along the surroundings of the first electrode portion 13. In this respect, the third electrode portion 15c is formed so as to face a side surface of the other end side of the first electrode layer 13 and both side surfaces crossing the side surface of the other end side of the first electrode layer 13.

The second electrode layer 15 is covered by an interlayer insulating film 18 that is formed on the semiconductor substrate 11 including the device isolation layer 12. The first electrode portion 15a and the second electrode portion 15b of the second electrode layer 15 are connected to the outside through vias 19, 20, respectively. The vias 19, 20 penetrate through the interlayer insulating film 18. Unlike the first electrode portion 15a of the second electrode layer 15, the second electrode portion 15b of the second electrode layer 15 penetrates through the interelectrode insulating film 14 and is electrically isolated from the first electrode layer 13 by burying the interlayer insulating film 18 in a groove that reaches an upper portion of the first electrode layer 13.

As shown in FIG. 2, a first capacitor C1 is formed in which the interelectrode insulating film 14 is sandwiched between the first electrode layer 13 and the second electrode portion 15b. Moreover, a second capacitor C2 is formed in which the device isolation layer is sandwiched between side surfaces of the first electrode layer 13 and the third electrode portion 15c.

Here, a height H1 from the main surface of the semiconductor substrate 11 to an upper surface of the first electrode layer 13 is formed to be equal to a height H2 from the main surface of the semiconductor substrate 11 to an upper surface of the device isolation layer 12.

The first capacitor C1 and the second capacitor C2 are expressed by the following equations, respectively.

C1=ε0ε1×ab/d1 (1)

C2=ε0ε2×(2a+b)c/d2 (2)

where ε0 is the permittivity of vacuum, ε1 is the relative permittivity of the interelectrode insulating film 14, d1 is the thickness of the interelectrode insulating film 14, ε2 is the relative permittivity of the device isolation layer 12, and d2 is the thickness of the device isolation layer 12 sandwiched between the side surfaces of the first electrode layer 13 and the third electrode portion 15c of the second electrode layer 15.

“a” is the length of the first electrode layer 13 overlapping with the second electrode portion 15b of the second electrode layer 15 shown in FIGS. 1A to 1C, “b” is the width of the first electrode layer 13, and “c” is the length by which the third electrode portion 15c protrudes inside the device isolation layer 12.

FIG. 3 is a cross-sectional view showing a main portion of a semiconductor integrated device of a comparative example. Here, the comparative example is about a semiconductor integrated device having no third electrode portion 15c of the second electrode layer 15.

As shown in FIG. 3, in the semiconductor integrated device of the comparative example, the second capacitor C2 in which the device isolation layer 12 is sandwiched between the side surfaces of the first electrode layer 13 and the third electrode portion 15c of the second electrode layer 15, is not formed. Only the first capacitor C1 is formed in which the interelectrode insulating film 14 is sandwiched between the first electrode layer 13 and the second electrode portion 15b of the second electrode layer 15.

Thus, as compared with the semiconductor integrated device of the comparative example, the semiconductor integrated device 10 of the embodiment is capable of obtaining a capacitor having a larger capacitance with the same element area.

Next, a manufacturing method of the semiconductor integrated device 10 will be described. FIGS. 4A to 5C are cross-sectional views each showing a main portion in manufacturing steps of the semiconductor integrated device.

As shown in FIG. 4A, after the first electrode layer 13 is formed on a main surface of the semiconductor substrate 11 through the insulating film 17, an unillustrated trench is formed by a reactive ion etching (RIE) method, and the device isolation layer (STI) 12 is formed by burying an insulating material in the trench. Subsequently, an upper surface of the device isolation layer 12 is made flush with an upper surface of the first electrode layer 13.

Here, in the first region 51, the upper surface of the device isolation layer 12 (second device isolation layer) is made lower than the upper surface of the first electrode layer 13 and higher than an upper surface of a first gate insulating film 17a.

The interelectrode insulating film 14 is formed on the first electrode layer 13 and the device isolation layer 12, and the opening 21 is formed in the interelectrode insulating film 14. Thereafter, a polysilicon layer 30 is formed through the interelectrode insulating film 14.

The insulating film 17 is formed simultaneously with the gate insulating film 17a. For example, a silicon oxide film is formed on a silicon substrate by a thermal oxidation method, and a silicon oxide film is nitriding by NH₃ gas. Thereafter, it is oxidizing so that an oxynitride film substitutes for the silicon oxide film. The oxynitride film serves as a first gate insulating film, and is generally referred to as a tunnel oxide film.

The first electrode layer 13 is formed simultaneously with a floating gate electrode 13a, and is made of amorphous silicon, for example.

The interelectrode insulating film 14 is formed simultaneously with a second gate insulating film 14a. Specifically, the interelectrode insulating film 14 is an ONO (SiO₂/SiN/SiO₂) film, and is generally referred to as an inter poly dielectric (IPD) film.

The polysilicon layer 30 is formed simultaneously with a control gate electrode 30a, and is a lower electrode of the control gate electrode.

As shown in FIG. 4B, a mask material 31 is formed on the polysilicon layer 30. An opening 31a surrounding the first electrode layer 13 is formed at a portion where the third electrode portion 15c is to be formed, and an opening 31b is formed at a portion corresponding to the opening 21 that connects the first electrode layer 13 to the first electrode portion 15a. Simultaneously, in the select transistor SG (the drawing is an enlarged view of the select transistor SG in FIG. 8B) within the first region 51, the mask material 31 is formed so as to cover the control gate electrode 30a. In the select transistor SG, an opening 31c is formed in a region where the opening P is to be formed in the second gate insulating film 14a.

As shown in FIG. 4C, by a RIE method using the mask material 31, a trench 32 is formed which penetrates through the polysilicon layer 30 and the interelectrode insulating film 14 and reaches the inside of the device isolation layer 12. Simultaneously, the opening 21 and the opening P are formed.

Specifically, after the etching of the interelectrode insulating film 14 is completed, the selection ratio is adjusted by changing the etching conditions such as the gas ratio. Accordingly, in the region where the device isolation layer 12 exists below the interelectrode insulating film 14, the device isolation layer 12 is etched continuously. In the region where the first electrode layer 13 exists below the interelectrode insulating film 14, the etching is performed on the condition that the first electrode layer 13 is less etched than the interelectrode insulating film 14. As a result, the opening 21 and the opening P are etched (over-etched) until certain portions of the first electrode layer 13 and the floating gate electrode 13a, respectively, so as to securely connect the upper and lower electrodes together. In addition, the trench 32 reaching the inside of the device isolation layer 12 can be formed.

If the depth of the trench 32 is too shallow, the capacitance of the second capacitor C2 is reduced. If the depth of the trench 32 is too deep, it takes wasteful time and cost for the processing. Accordingly, it is appropriate that the depth of the trench 32 is approximately equal to the thickness of the first electrode layer 13. Here, it is preferable to adjust the etching condition so that the depth of the trench 32 to be approximately equal to the thickness of the first electrode layer 13 can be formed by an over-etching time of the first electrode layer 13 and the floating gate electrode 13a.

As shown in FIG. 5A, a polysilicon film 33 is formed on the polysilicon film 30 by a CVD method so that the polysilicon film 33 would be buried in the trench 32. Thus, the second electrode layer 15 and the third electrode portion 15c are formed. Here, the third electrode portion 15c penetrates through the interelectrode insulating film 14 from a lower surface of the second electrode layer 15, and protrudes inside the device isolation layer 12.

The polysilicon film 33 is formed simultaneously with an upper electrode 33a of the control gate electrode 15a. The polysilicon films 30, 33 are the second electrode layer 15 and the control gate electrode 15a. On the other hand, in the first region 51, the upper electrode 33a penetrates through the second gate insulating film 14a, and electrically connects to the floating gate electrode 13a. As a result, the gate electrodes of the select NMOS transistors SG1.1, SG2.1 are formed.

As shown in FIG. 5B, a mask material 34 is formed on the polysilicon film 33. Simultaneously, an opening 34b is formed at a portion where the first electrode portion 15a is isolated from the second electrode portion 15b.

As shown in FIG. 5C, the polysilicon film 33, the polysilicon layer 30 and the interelectrode insulating film 14 are etched by a RIE method using the mask material 34. In this event, a groove 35b is formed, so that portions corresponding to the first electrode portion 15a and the second electrode portion 15b are electrically isolated from each other.

Thus, in the second electrode layer 15, the first electrode portion 15a connected to the first electrode layer 13 through the opening 21, and the second electrode portion 15b electrically isolated from the first electrode portion 15a are formed, and the first capacitor C1 and the second capacitor C2 can be obtained.

As described above, the semiconductor integrated device 10 of the embodiment includes the third electrode portion 15c of second electrode layer 15. The third electrode portion 15c penetrates through the interelectrode insulating film 14 from the lower surface of the second electrode portion 15b formed above the device isolation layer 12, then protrudes inside the device isolation layer 12, and faces the side surfaces of the first electrode layer 13.

As a result, in addition to the first capacitor C1 in which the interelectrode insulating film 14 is sandwiched between the first electrode layer 13 and the second electrode portion 15b, the second capacitor C2 can be obtained in which the device isolation layer 12 is sandwiched between the side surfaces of the first electrode layer 13 and the third electrode portion 15c. Accordingly, it is possible to obtain the semiconductor integrated device including a capacitor having a structure suitable for a larger capacitance.

No additional new processes are necessary to form the second capacitor C2. The second capacitor C2 can be formed simultaneously in the step of forming the polysilicon film 30 serving as a lower portion of the second electrode layer 15/a lower portion of the control gate electrode, in a step of processing the interelectrode insulating film 14 (EI step), and in the step of forming the polysilicon film 33 serving as an upper portion of the second electrode layer 15/an upper portion of the control gate electrode. Accordingly, a capacitor having a large capacitance can be formed in a peripheral circuit without the burden of processing.

The upper surface of the device isolation layer 12 of the semiconductor integrated device 10 is almost flush with the upper surface of the first electrode layer 13. On the other hand, in the memory cell, the upper surface of the device isolation layer 12 is lower than the upper surface of the floating gate 13a that is the same layer as the first electrode layer 13. In other words, the upper surface of the device isolation layer 12 of the memory cell is lower than the upper surface of the device isolation layer 12 of the semiconductor integrated device 10. To put it differently, the distance from the main surface of the semiconductor substrate 11 to the upper surface of the first device isolation layer 12 is larger than the distance from the main surface of the semiconductor substrate 11 to the upper surface of the second device isolation layer 12.

As a result, in the semiconductor device 10, the distance from the bottom surface of the second electrode layer 15 to the bottom surface of the device isolation layer 12 is long and thus breakdown voltage is improved while field inversion is unlikely to occur. Such effects can be remarkably obtained when the first electrode portion 15a or the second electrode portion 15b is connected to N8 of the charge pump circuit, shown in FIG. 9, generating a high voltage of about 20V.

Moreover, together with the above-mentioned effects, in the memory cell, the facing surface between the floating gate electrode 3A and the control gate electrode 5A is secured not only on the upper surface of the floating gate electrode 3A but also on the side surfaces of the floating gate electrode 3A, and thereby the coupling ratio of the memory cell MC is improved.

Here, a description has been given of a case where a reference surface for the height of the upper surface of the first electrode layer 13 and for the height of the upper surface of the device isolation layer 12 is the main surface of the semiconductor substrate 11. However, another surface, for example a surface opposite to the main surface of the semiconductor substrate 11, may be used as the reference surface. In short, it is sufficient that the upper surface of the first electrode layer 13 is flush with the upper surface of the device isolation layer 12.

A description has been given of a case where the end of the third electrode portion 15c is located at the same position as the first electrode layer 13, i.e., the distance from the main surface of the semiconductor substrate 11 to the lower surface of the third electrode portion 15c is almost equal to the distance from the main surface of the semiconductor substrate 11 to the lower surface of the first electrode layer 13, and where the third electrode portion 15c is formed along the surroundings of the first electrode layer 13. However, as long as the desired second capacitor C2 is obtained, the range of the distance of the third electrode portion 15c protruding inside the device isolation layer 12 and the range of the distance of the third electrode portion 15c extending along the surroundings of the first electrode layer 13 can be set appropriately.

As shown in FIGS. 1A to 5C, etching is performed so that a groove is formed to penetrate through the interelectrode insulating film 14 and to reach the upper portion of the first electrode layer 13. Then, electrical isolation is achieved by burying the insulating film 18 in the groove. As a result that a higher insulation isolation property can be obtained, as compared with a case where etching of the second electrode layer 15 is stopped at the upper surface of the interelectrode insulating film 14 and the first electrode portion 15a and the second electrode portion 15b are electrically isolated from each other.

Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A semiconductor integrated device comprising a main circuit and a peripheral circuit, the main circuit being formed in a first region on a main surface of a semiconductor substrate and having a first portion of a first electrode layer, a first portion of an interelectrode insulating film and a first portion of a second electrode layer respectively stacked in the order, the peripheral circuit being formed in a second region on the main surface of the semiconductor substrate and including:
a second portion of the first electrode layer electrically isolated by a first device isolation layer;
a second portion of the interelectrode insulating film formed on the second portion of the first electrode layer and the first device isolation layer and having an opening extending to the second portion of the first electrode layer;
a first electrode portion of a second portion of the second electrode layer formed on the second portion of the interelectrode insulating film and electrically connected to the second portion of the first electrode layer through the opening;
a second electrode portion of the second portion of the second electrode layer formed on the second portion of the interelectrode insulating film and electrically isolated from the second portion of the first electrode layer; and
a third electrode portion of the second portion of the second electrode layer formed so as to penetrate through the second portion of the interelectrode insulating film from a lower surface of the second electrode portion of the second portion of the second electrode layer formed above the first device isolation layer, then to protrude inside the first device isolation layer, and to face side surfaces of the second portion of the first electrode layer.

2. the semiconductor integrated device according to claim 1, wherein the first portion of the first electrode layer is electrically isolated by a second device isolation layer in the first region on the main surface of the semiconductor substrate, a distance from the main surface of the semiconductor substrate to an upper surface of the first device isolation layer is larger than a distance from the main surface of the semiconductor substrate to an upper surface of the second device isolation layer.

3. The semiconductor integrated device according to claim 1, wherein the main circuit has a memory transistor, the memory transistor has a first gate insulating film, a floating gate electrode layer, a second gate insulating film and a control gate electrode layer respectively sacked in the order, the first portion of the first electrode layer is the floating gate electrode layer, the first portion of the interelectrode insulating film is the second gate insulating film, the first portion of the second electrode layer is the control gate electrode.

4. The semiconductor integrated device according to claim 3, wherein the main circuit has a select transistor having the same structure as the memory transistor, a memory cell in which a plurality of memory transistors are connected in series is connected between a bit line and a source line via a pair of select transistors, the second gate insulating film of the select transistor has an opening extending to the floating gate electrode layer, the floating gate electrode layer is electrically connected to the control gate electrode through the opening.

5. The semiconductor integrated device according to claim 1, wherein the third electrode portion of the second portion of the second electrode layer is formed along the surroundings of the second portion of the first electrode layer.

6. The semiconductor integrated device according to claim 1, wherein a distance from the main surface of the semiconductor substrate to a lower surface of the third electrode portion of the second portion of the second electrode layer is almost equal to a distance from the main surface of the semiconductor substrate to a lower surface of the second portion of the first electrode layer.

7. The semiconductor integrated device according to claim 1, wherein the opening is formed on one end side of the second portion of the first electrode layer, the third electrode portion of the second portion of the second electrode layer is formed on the other end side of the second portion of the first electrode layer.

8. The semiconductor integrated device according to claim 5, wherein the third electrode portion of the second portion of the second electrode layer is formed so as to face a side surface of the other end side of the second portion of the first electrode layer and both side surfaces crossing the side surface of the other end side of the second portion of the first electrode layer.

9. The semiconductor integrated device according to claim 1, wherein the first electrode layer is formed on the main surface of the semiconductor substrate through an insulating film.

10. The semiconductor integrated device according to claim 2, wherein the first device isolation layer and the second device isolation layer are Shallow Trench Isolation obtained by burying an insulating material in a trench formed in the semiconductor substrate.

11. The semiconductor integrated device, comprising:
a first electrode layer electrically isolated by a first device isolation layer;
an interelectrode insulating film formed on the first electrode layer and the first device isolation layer and having an opening extending to the first electrode layer;
a first electrode portion of a second electrode layer formed on the interelectrode insulating film and electrically connected to the first electrode layer through the opening;
a second electrode portion of the second electrode layer formed on the interelectrode insulating film and electrically isolated from the first electrode layer; and
a third electrode portion of the second electrode layer formed so as to penetrate through the interelectrode insulating film from a lower surface of the second electrode portion of the second portion of the second electrode layer formed above the first device isolation layer, then to protrude inside the first device isolation layer, and to face side surfaces of the first electrode layer.

12. The semiconductor integrated device according to claim 11, wherein the third electrode portion of the second portion of the second electrode layer is formed along the surroundings of the second portion of the first electrode layer.

13. The semiconductor integrated device according to claim 11, wherein a distance from the main surface of the semiconductor substrate to a lower surface of the third electrode portion of the second portion of the second electrode layer is almost equal to a distance from the main surface of the semiconductor substrate to a lower surface of the second portion of the first electrode layer.

14. The semiconductor integrated device according to claim 11, wherein the opening is formed on one end side of the second portion of the first electrode layer, the third electrode portion of the second portion of the second electrode layer is formed on the other end side of the second portion of the first electrode layer.

15. The semiconductor integrated device according to claim 12, wherein the third electrode portion of the second portion of the second electrode layer is formed so as to face a side surface of the other end side of the second portion of the first electrode layer and both side surfaces crossing the side surface of the other end side of the second portion of the first electrode layer.

16. The semiconductor integrated device according to claim 11, wherein the first electrode layer is formed on the main surface of the semiconductor substrate through an insulating film.

17. The semiconductor integrated device according to claim 11, wherein the first device isolation layer and the second device isolation layer are Shallow Trench Isolation obtained by burying an insulating material in a trench formed in the semiconductor substrate.
